(19) United States
(12) Patent Application Publication
(10) Pub. No.: US 2012/0001264 A1
(43) Pub. Date: Jan. 5, 2012

(54) ETCHANTS AND METHODS OF FABRICATING SEMICONDUCTOR DEVICES USING THE SAME

(76) Inventors: Hong-suk Kim, Yongin-si (KR); Jin-gyun Kim, Yongin-si (KR); Hun-Hyeong Lim, Hwaseong-si (KR); Ki-hyun Hwang, Seongnam-si (KR); Jae-Young Ahn, Seongnam-si (KR); Jun-kyu Yang, Seoul (KR)

(21) Appl. No.: 13/173,360

(22) Filed: Jun. 30, 2011

(30) Foreign Application Priority Data
Jul. 2, 2010 (KR) 10-2010-0063873

(51) Int. Cl. H01L 21/28; C09K 13/04; H01L 27/088

(52) U.S. Cl. 257/368; 438/587; 252/79.2; 257/E27.06; 257/E21.19

(57) ABSTRACT

Provided according to embodiments of the present invention are methods of fabricating semiconductor devices using an etchant. In some embodiments, the etchant may be highly selective and may act to reduce interference between wordlines in the semiconductor device. In some embodiments of the invention, provided are methods of fabricating a semiconductor device that include forming a plurality of gate patterns on a substrate; forming first insulation layers between the gate patterns; wet-etching the first insulation layers to form first insulation layer residues; and forming air gaps between the plurality of gate patterns. Related etchant solutions and semiconductor devices are also provided.

### CROSS-REFERENCE TO RELATED APPLICATIONS

This application claims the benefit of Korean Patent Application No. 10-2010-0063873, filed on Jul. 2, 2010, in the Korean Intellectual Property Office, the disclosure of which is incorporated herein by reference in its entirety.

### BACKGROUND

The present invention relates to etchants and to methods of fabricating semiconductor devices using the same.

Due to an increase in the integration of semiconductor devices, the width of separating layers in devices may be reduced, and thus, intervals between adjacent wordlines and between adjacent floating gates may also be reduced. As such, there may be interference due to capacitance between the wordlines, which may shift the cell threshold voltage, which in turn, may decrease the reliability of the semiconductor device.

### SUMMARY

Provided according to embodiments of the present invention are methods of fabricating semiconductor devices using an etchant. In some embodiments, the etchant may be highly selective and may act to reduce interference between wordlines in the semiconductor device.

In some embodiments of the invention, provided are methods of fabricating a semiconductor device that include forming a plurality of gate patterns on a substrate; forming first insulation layers between the gate patterns; wet-etching the first insulation layers to form first insulation layer residues; and forming air gaps between the plurality of gate patterns.

In some embodiments of the invention, the wet-etching is performed using an etchant that includes phosphoric acid (H₃PO₄) and silicon phosphate (Si₃(PO₄)₄). In some embodiments, the concentration of Si in the etchant is from about 10 to about 1000 ppm with respect to the total weight of the etchant solution.

In some embodiments of the invention, the air gaps are formed between the substrate and the first insulation residues. In some embodiments, the methods include forming a second insulation layer on the substrate and on the gate patterns before forming the first insulation layers, wherein the first insulation layers are selectively etched over the second insulation layer.

In some embodiments of the invention, the methods include heating the first insulation residues to form third insulation layers. In some embodiments, the third insulation layers have an etching selectivity different from that of the first insulation layers.

In some embodiments, the third insulation layers are on top of the gate patterns. The third insulation layers may contact each other, or may be sufficiently apart so that the third insulation layers to not contact each other but have slits therebetween. In some embodiments, the methods include forming a fourth insulation layer on the third insulation layers. In some embodiments, the fourth insulation layer may cover the slits between adjacent third insulation layers.

Provided according to some embodiments of the invention are methods of fabricating a semiconductor device that include forming a plurality of gate patterns on a substrate; forming a first oxide layer on the substrate and on the gate patterns; forming nitride layers between the gate patterns; forming residues of the nitride layers by etching the nitride layers using an etchant that includes phosphoric acid and silicon phosphate; and forming second oxide layers by heating the residue, wherein air gaps are formed between the plurality of gate patterns.

Also provided herein are etchants that include phosphoric acid and silicon phosphate. In some embodiments, the concentration of Si in the etchant is from about 10 to about 1000 ppm with respect to the total weight of the etchant solution.

Also provided herein are methods of forming an oxide layer that include forming a nitride residue by etching nitride layers using an etchant including phosphoric acid (H₃PO₄) and silicon phosphate (Si₃(PO₄)₄); and forming an oxide layer by heating the nitride residue.

Further provide herein are semiconductor devices that are formed by a method that includes forming a plurality of gate patterns on a substrate; forming first insulation layers between the gate patterns; wet-etching the first insulation layers to form first insulation layer residues; and forming air gaps between the plurality of gate patterns. Also provided are semiconductor devices that include a plurality of gate patterns; and an oxide layer on the plurality of gate patterns, such that air gaps are present in the space enclosed by the gate patterns and the oxide layer.

### BRIEF DESCRIPTION OF THE DRAWINGS

Exemplary embodiments of the inventive concept will be more clearly understood from the following detailed description taken in conjunction with the accompanying drawings in which:

FIGS. 1 through 5 are sectional views showing a method of fabricating a semiconductor device according to some embodiments of the invention;

FIGS. 6 and 7 are sectional views showing a method of fabricating a semiconductor device according to some embodiments of the invention;

FIG. 8 is a plan view of a semiconductor device according to some embodiments of the invention;

FIG. 9 is a sectional view taken along a line A-A′ of FIG. 8;

FIG. 10 is a sectional view taken along a line B-B′ of FIG. 8;

FIGS. 11 through 21B are sectional views sequentially showing steps in a method of fabricating a semiconductor device according to some embodiments of the invention;

FIGS. 22 through 29 are sectional views sequentially showing steps in a method of fabricating the semiconductor device according to some embodiments of the invention;

FIG. 30 is a diagram showing a card including a semiconductor device that is fabricated using a method of fabricating a semiconductor device according to some embodiments of the invention; and

FIG. 31 is a diagram showing a system including a semiconductor device that is fabricated using a method of fabricating a semiconductor device according to some embodiments of the invention.

### DETAILED DESCRIPTION OF THE EMBODIMENTS

The inventive concept will now be described more fully with reference to the accompanying drawings, in which exemplary embodiments of the inventive concept are shown.

The inventive concept may, however, be embodied in many different forms and should not be construed as being limited to the embodiments set forth herein; rather, these embodiments are provided so that this disclosure will be thorough and complete, and will fully convey the concept of the inventive concept to those skilled in the art.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Embodiments of the inventive concept are described herein with reference to cross-section illustrations that are schematic illustrations of embodiments (and intermediate structures) of the inventive concept. As such, variations from the shapes of the illustrations as a result, for example, of manufacturing techniques and/or tolerances, are to be expected. Thus, embodiments of the inventive concept should not be construed as limited to the particular shapes of regions illustrated herein but are to include deviations in shapes that result, for example, from manufacturing.

Provided according to embodiments of the present invention are methods of fabricating semiconductor devices using an etchant. In some embodiments, the etchant may be highly selective and may act to reduce interference between wordlines in the semiconductor device.

In some embodiments of the invention, provided are methods of fabricating a semiconductor device that include forming a plurality of gate patterns on a substrate; forming first insulation layers between the gate patterns; wet-etching the first insulation layers to form first insulation layer residues; and forming air gaps between the plurality of gate patterns.

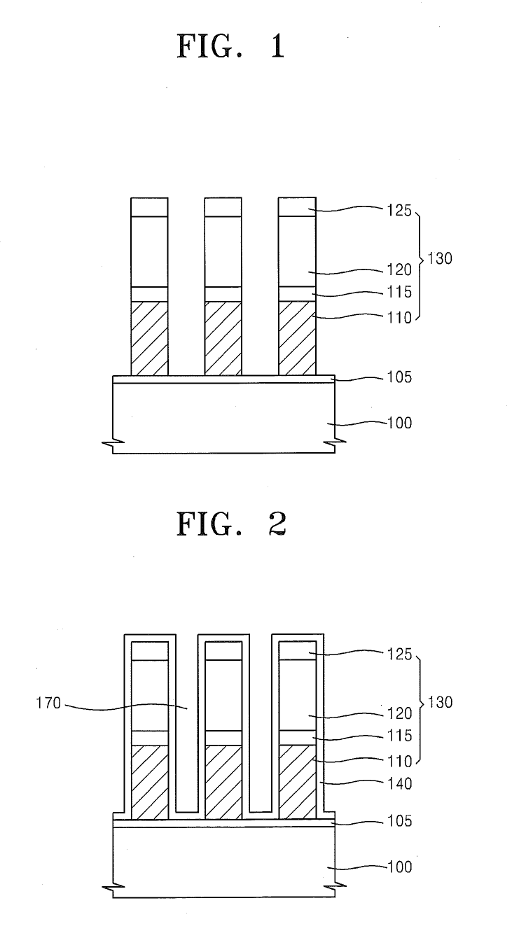

FIGS. 1 through 5 are sectional views showing a method of fabricating a semiconductor device according to some embodiments of the invention.

Referring to FIG. 1, in some embodiments, a tunneling insulation layer 105 may be formed on a substrate 100. The substrate 100 may be a semiconductor substrate 100 and may include, for example, silicon, silicon-on-insulator, silicon-on-sapphire, germanium, silicon-germanium, gallium-arsenide or a combination thereof. In some embodiments, the tunneling insulating layer may be formed from silicon oxide (SiO₂), silicon nitride (Si₃N₄), silicon oxinitride (SiON), hafnium oxide (HfO₂), hafnium silicon oxide (HfSiₓO_{y}), aluminum oxide (Al₂O₃), and zirconium oxide (ZrO₂), or a combination thereof. Additionally, in some embodiments, the tunneling insulation layer 105 may be formed by stacking a plurality of insulating layers.

Next, a plurality of gate patterns 130 may be formed on the tunneling insulation layer 105. In some embodiments, each of the gate patterns 130 may include a first conductive layer pattern 110, a blocking insulation layer pattern 115, a second conductive layer pattern 120, and a capping insulation layer pattern 125.

In some embodiments, the first conductive layer pattern 110 may include poly-silicon doped with an impurity. For example, the first conductive layer pattern 110 may be formed by depositing poly-silicon onto the tunneling insulation layer 105 through chemical vapor deposition (CVD), e.g. low pressure CVD (LPCVD) using SiH₄ or Si₂H₆ and PH₃ gas, and then performing an impurity doping operation.

In some embodiments, the blocking insulation layer 115 may be formed by sequentially forming a lower dielectric layer (not shown), a high-k layer (not shown), and an upper dielectric layer (not shown) on a surface of the first conductive layer pattern 110 in the order stated. In some embodiments, each of the lower dielectric layer and the upper dielectric layer may include a silicon oxide. In some embodiments where the lower dielectric layer and the high-k dielectric layer are both silicon oxide layers, the lower dielectric layer and the high-k dielectric layer may be formed of the same material, have the same structure, may be single layers and/or may contain, for example, one or more of SiO₂, carbon-doped SiO₂, fluorine-doped SiO₂ porous SiO₂ and combinations thereof. Furthermore, in some cases, the silicon oxide layers may include high temperature oxide (HTO) layers formed by performing high temperature oxidation using SiH₂Cl₂ and water vapor as a source gas, and the HTO layer may exhibit excellent pressure-resistance and excellent time dependent dielectric breakdown (TDDB) characteristics. However, this is only an example, and other methods and materials may be used in other embodiments of the invention.

In some embodiments of the invention, the high-k layer may have a higher permittivity than a silicon oxide layer or a silicon nitride layer. For example, in some embodiments, the high-k layer may include a metal oxide. In some cases, the metal oxide layer may be formed by stacking a plurality of layers, and in some embodiments, may include aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), praseodymium oxide (Pr₂O₃), or a combination thereof.

In some embodiments, the second conductive layer pattern 120 may include poly-silicon doped with an impurity, metal, metal oxide, metal silicide, or a combination thereof. In some cases, the second conductive layer pattern 120 may be formed by stacking a plurality of layers, and in some cases, may include poly-silicon, aluminum (Al), gold (Au), beryllium (Be), bismuth (Bi), cobalt (Co), hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), tantalum (Ta), tellurium (Te), titanium (Ti), tungsten (W), zinc (Zn), zirconium (Zr), nitrides thereof, silicides thereof or combinations thereof. However, other structures and materials may be used for the second conductive layer pattern 12 in other embodiments of the invention.

Referring to FIG. 2, in some embodiments, a first insulation layer 140 may be formed on the substrate 100 and the gate patterns 130. The first insulation layer 140 may be formed of a material having an etching selectivity with respect to the capping insulation layer 125. For example, in some embodiments, the capping insulation layer 125 may be formed of silicon nitride, and the first insulation layer 140 may be formed of silicon oxide having an etching selectivity with respect to the capping insulation layer 125. The term “etching selectivity” means that the two layers are etched at different rates and, in some cases, one of the layers may be removed by an etchant while the other layer remains significantly intact.

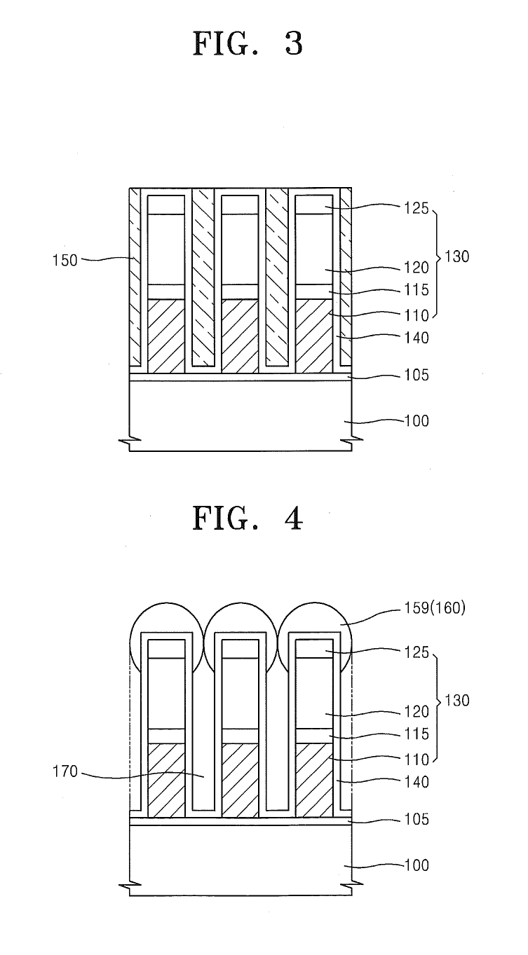

Referring to FIG. 3, second insulation layers 150 may be formed between the gate patterns 130. The second insulation layers 150 may be formed of a material having an etching selectivity with respect to the first insulation layer 140. For example, in some embodiments, the first insulation layer 140 may be formed of silicon oxide, whereas the second insulation layers 150 may be formed of silicon nitride having an etching selectivity with respect to the first insulation layer 140. That is the second insulation layers 150 may be selectively etched over the first insulation layer 140.

Referring to FIG. 4, the second insulation layers 150 may be etched. For example, in some embodiments where the second insulation layers 150 are formed of silicon nitride, the second insulation layers 150 may be etched by using an etchant that includes phosphoric acid (H₃PO₄) and silicon phosphate (Si₃(PO₄)₄). The etching of the second insulating layer may form a residue 159, which may include silicon oxide SiOₓ. This residue may be formed by the reactions described in Chemical Equations 1 and 2 below. As the second insulation layers 150 are etched and the residue 159 is formed, an air gap 170 may be formed between the first insulation layer 140 and the residue 159. In some cases, the air gap 170 formed between the gate patterns 130 may improve interference between wordlines in the semiconductor device.

Si₃N₄+4H₃PO₄->Si₃(PO₄)₄+4NH₃ [Chemical Equation 1]

Si₃(PO₄)₄+H3PO4+Si₃N₄->SiOₓ [Chemical Equation 2]

As discussed above, the etchant may be used to etch the silicon nitride layer between the gate patterns 130 to form the residue 159, which in turn, may form the air gap 170 between the gate patterns 130. When the etchant described by Chemical Equation 1 and Chemical Equation 2 is used, the silicon nitride may be etched by the phosphoric acid. The etching may result in a Si-rich solution and the selectivity of the etchant may be adjusted by including a Si-rich silicon phosphate, such as Si₃(PO₄)₄, with the phosphoric acid. In some embodiments, the concentration of Si in the etchant is in a range of about 10 to about 1000 ppm, that is, from about 0.01 g/kg to about 1 g/kg, with respect to the total weight of the etchant solution. This etchant may be highly selective for etching silicon nitride over silicon oxide.

When silicon nitride is etched by using the etchant described herein, a residue 159 containing silicon oxide (Siₓ) may be formed as shown in Chemical Equation 2 above. The residue 159 may be formed on top of the gate patterns 130 as the second insulation layers 150 of the silicon nitride are etched from the top. In some embodiments, etching may be performed at a temperature in a range of from about 25° C. to about 200° C. In some embodiments, etching may be performed for a time period in a range from about 5 minutes to about 30 minutes. In particular embodiments, the second insulation layers 150 may be etched using an etchant that includes Si at a concentration of about 100 ppm at 160° for 10 minutes. The temperature and the period of time for performing the etching operation may be adjusted according to the thickness of the second insulation layers 150 and the number of substrates 100.

The first insulation layer 140 may act to protect the gate patterns 130 from the etchant. For example, in some embodiments, the first insulation layer 140 may be formed of a material having an etching selectivity with respect to the second insulation layers 150, and thus the first insulation layer 140 may function as an etching mask to prevent the gate patterns 130 from being etched by the high selectivity etchant.

The residue 159, which may include amorphous silicon oxide (SiOₓ), may be converted to third insulation layers 160, which includes silicon dioxide (SiO₂), by heating the residue 159. In some embodiments, the third insulation layers 160 may contact each other, to form enclosed air gaps 170.

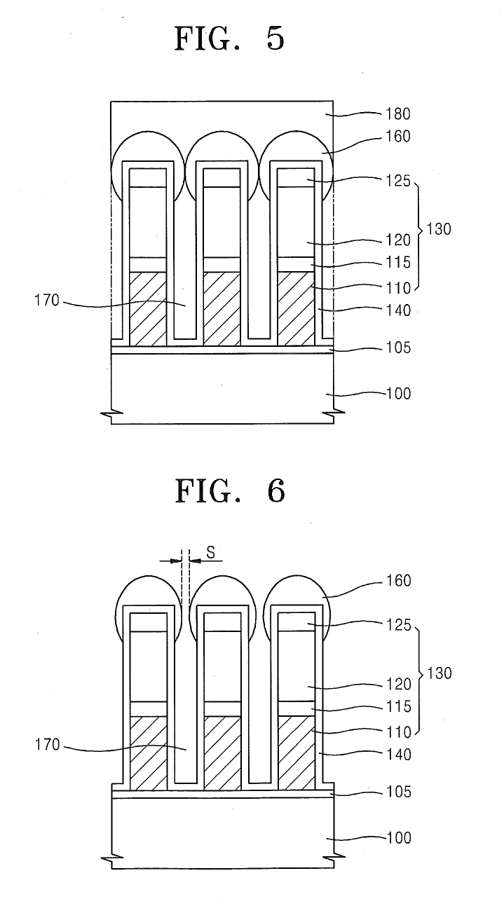

Referring to FIG. 5, in some embodiments, a fourth insulation layer 180 may be formed on the third insulation layers 160, and in some cases, the fourth insulation layer 180 may be planarized. The planarization may be performed by any suitable method, including, for example, performing a chemical mechanical polishing (CMP) operation, an etchback operation, or a combination thereof.

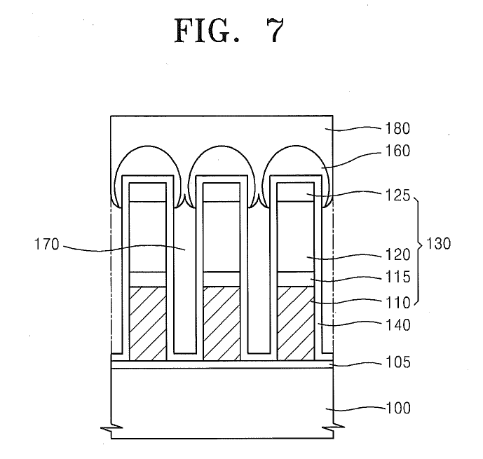

FIGS. 6 and 7 are sectional views showing a method of fabricating a semiconductor device according to some embodiments of the invention. These methods are modified from the methods described with respect to FIGS. 1 through 5, and so redundant description of the materials and methods previously described will be omitted.

Referring to FIGS. 6 and 7, when the residue 159 is heated and converted to the third insulation layers 160, which may include SiO₂, the third insulation layers 160 may be a distance apart from adjacent layers, and such distances may be predetermined. Therefore, slits may be formed between adjacent third insulation layers 160. Next, in some embodiments, the fourth insulation layer 180 may be formed on the third insulation layers 160, and in some embodiments, the fourth insulation layer 180 may be planarized, for example, by performing a chemical mechanical polishing (CMP) operation, an etchback operation, or a combination thereof.

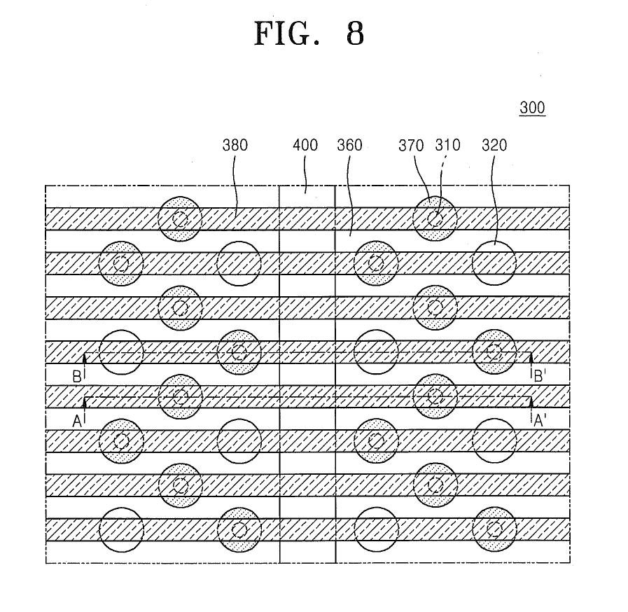

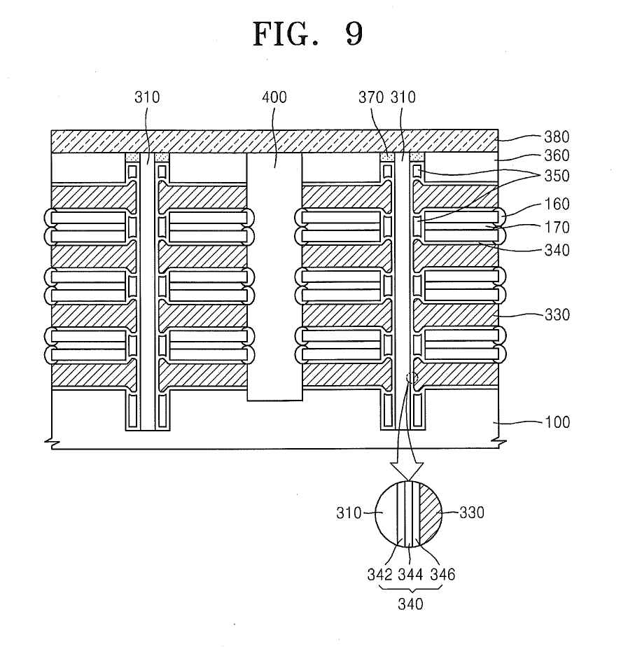

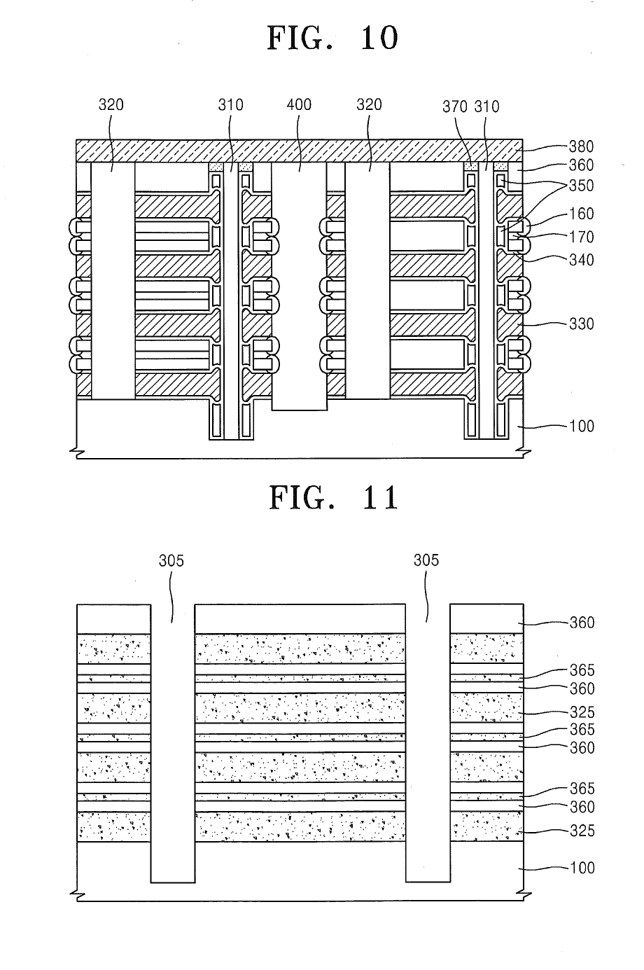

FIG. 8 is a plan view of a semiconductor device 300 according to some embodiments of the invention. FIG. 9 is a sectional view taken along a line A-A′ of FIG. 8, and FIG. 10 is a sectional view taken along a line B-B′ of FIG. 8.

Referring to FIGS. 8 through 10, the semiconductor device 300 may include the substrate 100, channel layers 310, supporting insulation layers 320, gate conductive layers 330, gate insulation layers 340, first air gaps 170, second air gaps 350, separating insulation layers 400, first insulation layers 360, second insulation layers 370, the third insulation layers 160, and a bitline conductive layer 380.

Referring to FIG. 8, in some embodiments, the channel layers 310 may be arranged in a zig-zag fashion. Furthermore, in some embodiments, the channel layers 310 arranged in a zig-zag fashion may surround the supporting insulation layers 320. For example, the channel layers 310 and the supporting insulation layers 320 may be arranged between the separating insulation layers 400, and the channel layers 310 between the separating insulation layers 400 may be arranged in a zig-zag fashion. The supporting insulation layers 320 may be arranged in spaces between the channel layers 310 arranged in a zig-zag fashion and the separating insulation layers 400. In other words, each of the supporting insulation layers 320 may be surrounded by the separating insulation layers 400 and the channel layers 310, and thus the supporting insulation layers 320 between the separating insulation layers 400 may be arranged in a reverse zig-zag fashion.

Referring to FIGS. 9 and 10, the substrate 100 may include a semiconductor material. Examples of semiconductor materials include a Group IV semiconductor, a group III-V compound semiconductor and a group II-VI compound semiconductor. Examples of group IV semiconductors include silicon, germanium and silicon-germanium. In some embodiments, the substrate 100 may include a bulk wafer, an epitaxial layer, a silicon-on-insulator (SOI) layer and/or a semiconductor-on-insulator (SEOI) layer. Other materials may also be used in other embodiments of the invention.

In some embodiments of the invention, the channel layers 310 may protrude and extend in a direction perpendicular to the substrate 100. For example, the channel layers 310 may be formed as multi-crystal structures or single-crystal epitaxial layers. Furthermore, in some embodiments, the channel layers 310 may include silicon, germanium and/or silicon-germanium. Although pillar-type channel layers 310 are shown in FIGS. 9 and 10, other configurations may be used. For example, the channel layers 310 may also be shaped as macaroni-type channel layers. In this case, the semiconductor device 300 may further include an insulation layer (not shown) for filling the interior of the macaroni-type channel layers.

In some embodiments of the invention, the gate conductive layers 330 may be stacked on side surfaces of the channel layers 310. For example, the first insulation layers 360 and the gate conductive layers 330 may be alternately stacked on side surfaces of the channel layers 310 and may surround the channel layers 310. The gate conductive layers 330 may contain any suitable material, including, for example, poly-silicon, aluminum (Al), ruthenium (Ru), tantalum nitride (TaN), titanium nitride (TiN), tungsten (W), tungsten nitride (WN), hafnium nitride (HfN), tungsten silicide (WSi) or a combination thereof.

In some embodiments of the invention, the first insulation layers 360 may be apart from the channel layers 310 and may be arranged on and/or beneath the gate conductive layers 330. For example, in some embodiments, the first insulation layers 360 may be arranged between the gate conductive layers 330 and/or on the gate conductive layers 330. Furthermore, in some cases, the thickness of the topmost first insulation layer 360 may be greater than those of the other first insulation layers 360. Additionally, the first insulation layers 360 may include the first air gaps 170 therein. Specifically, in some embodiments, the first air gaps 170 in the first insulation layers 360 may be formed between the gate insulation layers 340 and the third insulation layer 160. Interference between the gate conductive layers 330 may be reduced by the first air gaps 170.

In some embodiments, the second insulation layers 370 may directly contact the upper portion of the channel layers 310. In some embodiments, the second insulation layers 370 may be directly interposed between the first insulation layers 360 and the channel layers 310. For example, the second insulation layers 370 may be interposed between the topmost first insulation layer 360 and the channel layers 310. Furthermore, the second insulation layers 370 may be interposed between a gate insulation layer 340 and the bitline conductive layer 380. In some cases, the etching selectivity of the first insulation layers 360 and the second insulation layers 370 may be substantially the same. In some cases, the thickness of the first insulation layers 360 may be greater than the thickness of the second insulation layers 370. Specifically, in the direction perpendicular to the substrate 100, the thickness of the second insulation layers 370 may be less than the thickness of the first insulation layers 360. Furthermore, if the second insulation layers 370 are viewed from above as shown in FIG. 1, the second insulation layers 370 may have a ring type structure surrounding the channel layers 310.

In some embodiments, the gate insulation layers 340 may be interposed between the gate conductive layers 330 and the channel layers 310. Specifically, each of the gate insulation layers 340 may be formed to surround the gate conductive layer 130. Therefore, each of the gate insulation layers 340 may be interposed between the gate conductive layer 130 and the first insulation layers 360 and between the gate conductive layers 330 and the channel layers 310. Furthermore, the gate insulation layers 340 may be formed to surround sidewalls of the channel layers 310.

In some embodiments of the invention, the gate insulation layers 340 may include a plurality of gate insulation layers, such as a tunneling insulation layer 342, a charge storage layer 344, and a blocking insulation layer 346, which may be sequentially stacked on side surfaces of the channel layers 310. For example, the gate insulation layers 340 may include the tunneling insulation layer 342, the charge storage layer 344, and the blocking insulation layer 346, which may be sequentially stacked on the channel layers 310. The tunneling insulation layer 342, the charge storage layer 344, and the blocking insulation layer 346 may form a storage medium. In some embodiments, each of the tunneling insulation layer 342, the charge storage layer 344, and the blocking insulation layer 346 may independently be formed of silicon oxide (SiO₂), silicon nitride (Si₃N₄), silicon oxinitride (SiON), aluminum oxide (Al₂O₃), aluminum nitride (AlN), hafnium oxide (HfO₂), hafnium silicon oxide (HfSiO), hafnium silicon oxinitride (HfSiON), hafnium oxinitride (HfON), hafnium aluminum oxide (HfAlO), zirconium oxide (ZrO₂), tantalum oxide (Ta₂O₃), hafnium tantalum oxide (HfTaₓO_{y}), lanthanum oxide (La₂O₃), lanthanum aluminum oxide (LaAlₓO_{y}), lanthanum hafnium oxide (LaHfₓO_{y}), or a combination thereof. For example, in some cases, the tunneling insulation layer 342 may be formed of silicon oxide, the charge storage layer 344 may be formed of silicon nitride, and the blocking insulation layer 346 may be formed of metal oxide.

In some embodiments of the invention, in the direction perpendicular to the substrate 100, second air gaps 350 may be arranged between the gate conductive layers 330 or may be interposed between the topmost gate conductive layer 330 and the second insulation layers 370. In some cases, the second air gaps 350 may be formed by depositing the gate insulation layers 340 with poor step coverage during fabrication of the semiconductor device 300. In the direction parallel to the substrate 100, the second air gaps 350 may be interposed between the first insulation layers 360 and the channel layers 310. Furthermore, the gate insulation layers 340 may be formed between the second air gaps 350 and the channel layers 310 and/or between the second air gaps 350 and the first insulation layers 360.

In some embodiments, the separating insulation layers 400 may be arranged between the channel layers 310 and may protrude and extend in a direction perpendicular to the substrate 100. In some cases, the separating insulation layers 400 may be connected to the first insulation layer 360. The bitline conductive layer 380 may be formed on the channel layers 310 and may extend in a direction parallel to the substrate 100. In some embodiments, the bitline conductive layer 380 may contact the first insulation layer 360, the second insulation layers 370, and the separating insulation layers 400.

In some embodiments, the supporting insulation layers 320 may be interposed between the channel layers 310 and the separating insulation layers 400, and may protrude and extend in a direction perpendicular to the substrate 100. In some cases, the supporting insulation layers 320 may be connected to the first insulation layers 360. Specifically, in some cases, only the first insulation layers 360 are interposed between the supporting insulation layers 320 and the separating insulation layers 400. The bitline conductive layer 380 may contact the first insulation layers 360, the second insulation layers 370, the separating insulation layers 400, and the supporting insulation layers 320. In some embodiments, the etching selectivity of the supporting insulation layers 320 and the first insulation layers 360 may be substantially the same.

FIGS. 11 through 21B are sectional views sequentially showing each operation of a method of fabricating the semiconductor device 300 according to embodiments of the invention. Methods of fabricating the semiconductor device 300 according to some embodiments of the invention are shown in FIG. 10, and so any redundant description will be omitted.

Referring to FIG. 11, in some embodiments, a plurality of first sacrificial insulation layers 325 and a plurality of first insulation layers 360 are alternately stacked on the substrate 100. In some embodiments, the first sacrificial insulation layers 325 may be formed of a material having an etching selectivity different from that of the first insulation layers 360.

Additionally, in some embodiments, second sacrificial insulation layers 365 for forming air gaps may be formed in the first insulation layers 360. In this case, the first sacrificial insulation layers 325, the first insulation layers 360, the second sacrificial insulation layers 365, and the first insulation layers 360 may be alternately stacked. In some embodiments, the thickness of the second sacrificial insulation layer 365 is less than that of the first sacrificial insulation layer 325. Furthermore, the second sacrificial insulation layers 365 may be formed of a material having an etching selectivity different from that of the first insulation layers 360. For example, the first and second sacrificial insulation layers 325 and 365 may be formed of silicon nitride, whereas the first insulation layers 360 may be formed of silicon oxide. Next, in some embodiments, the first sacrificial insulation layers 325, the second sacrificial insulation layers 365, and the first insulation layers 360 may be etched to form a plurality of channel holes 305.

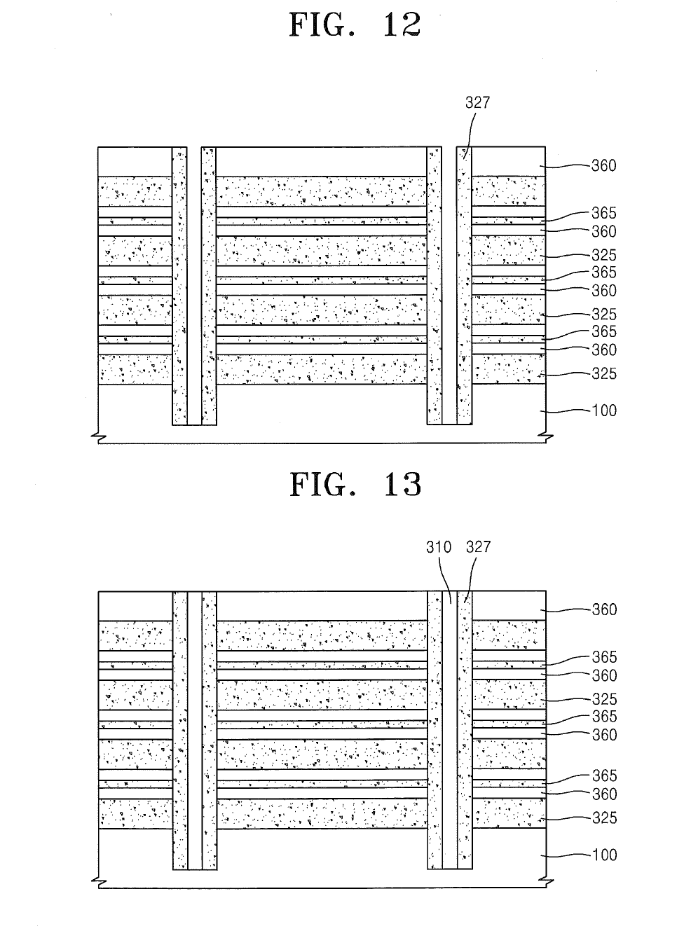

Referring to FIG. 12, third sacrificial insulation layers 327 may be formed on sidewalls of the channel holes 305. In some embodiments, the third sacrificial insulation layers 327 may be formed of a material having the same etching selectivity as the first sacrificial insulation layers 325. For example, the third sacrificial insulation layers 327 may be formed of silicon nitride.

Referring to FIG. 13, in some embodiments, the channel layers 310 contacting the third sacrificial insulation layers 327 may be formed. In this case, the channel layers 310 may be formed in the third sacrificial insulation layers 327 having a single layer structure. Therefore, formation of wrinkles on the channel layers 310 due to a double layer structure in the conventional method may be eliminated. Although FIG. 13 shows the channel layers 310 as pillar-type channel layers, the channel layers 310 may also be macaroni-type channel layers as described above. In this case, a process for forming a pillar insulation layer filling the interior of the channel layers 310 may be added after the formation of the channel layers 310 contacting the third sacrificial insulation layers 327.

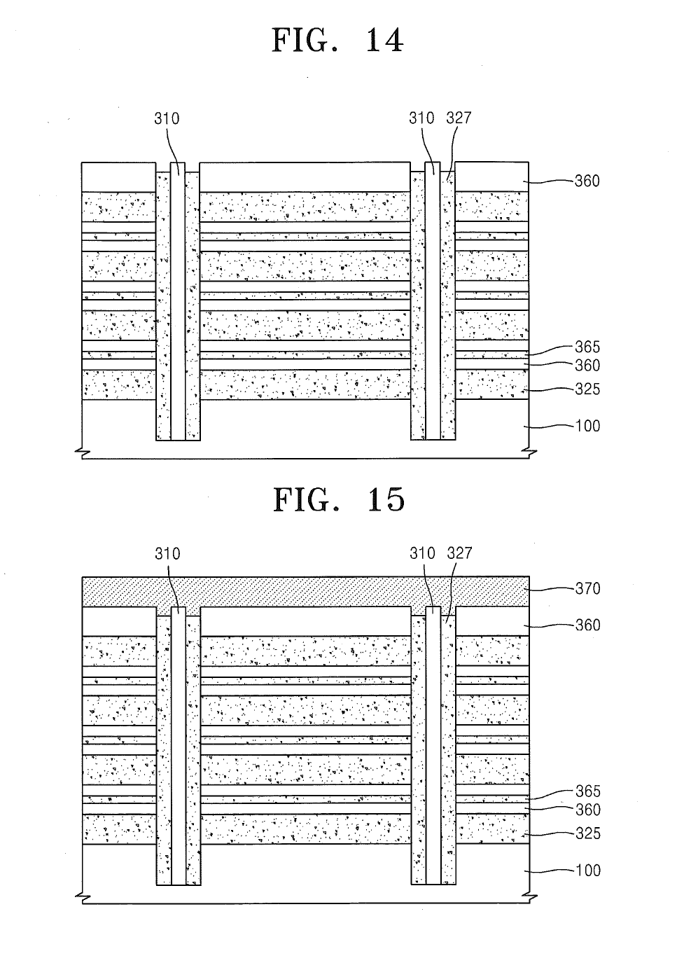

Referring to FIG. 14, sidewalls of the topmost first insulation layer 360 and sidewalls of the channel layers 310 may be exposed by etching the upper portions of the third sacrificial insulation layers 327 to a first depth. In a direction perpendicular to the substrate 100, the first depth may be less than the thickness of the topmost first insulation layer 360.

Referring to FIG. 15, the second insulation layers 370 may be formed on the third sacrificial insulation layers 327. Specifically, the second insulation layers 370 may be formed such that the second insulation layers 370 contact the sidewalls of the topmost first insulation layer 360 and the sidewalls of the channel layers 310. The second insulation layers 370 may prevent channels from being toppled or lifted during a pull back process, in which the first through third sacrificial insulation layers 325, 365, and 327 are etched.

Referring to FIG. 16, to perform the pull back process, in which the first through third sacrificial insulation layers 325, 365, and 327 are etched, a plurality of wordline holes 405 may be formed by etching the second insulation layers 370, the first and second sacrificial insulation layers 325 and 365, and the first insulation layers 360. In this case, each of the wordline holes 405 may be arranged between the channel layers 310.

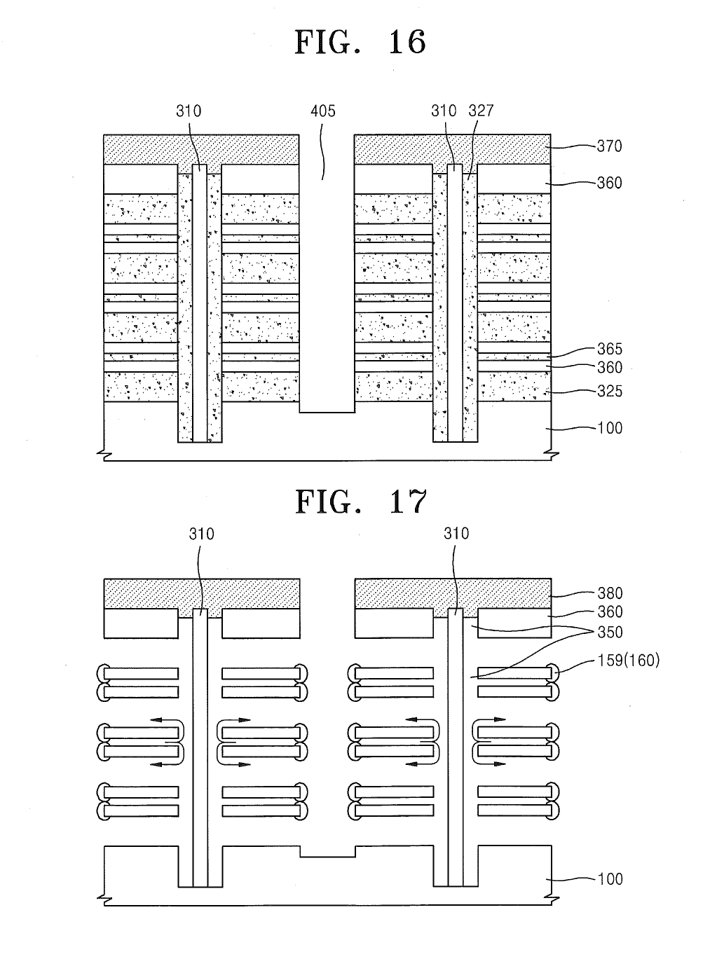

Referring to FIG. 17, the first insulation layers 360 and the channel layers 310 may be exposed by etching the first sacrificial insulation layers 325, the second sacrificial insulation layers 365, and the third sacrificial insulation layers 327. For example, the first through third sacrificial insulation layers 325, 365, and 327 may be formed of silicon nitride, whereas the first insulation layers 360 and the second insulation layers 370 may be formed of silicon oxide. In this case, the first insulation layers 360, the second insulation layers 370, and the channel layers 310 may be exposed by removing the first through third sacrificial insulation layers 325, 365, and 327 via a wet etching operation using phosphorous acid (H₃PO₄). In particular, the first through third sacrificial insulation layers 325, 365, and 327 may be removed by using an etchant that includes phosphoric acid (H₃PO₄) and silicon phosphate (Si₃(PO₄)₄). Since this etchant is as described above with reference to FIG. 4, redundant description will be omitted.

In the case where the second sacrificial insulation layers 365 are etched by using the high selectivity etchant, residue of the second sacrificial insulation layers 365 may be formed on ends of the first insulation layers 360. Specifically, the high selectivity etchant may flow in through the wordline holes 405, and the first through third sacrificial insulation layers 325, 365, and 327 may be etched. In this case, the residue 159 of the second sacrificial insulation layers 365 etched via the etchant may remain on ends of the first insulation layers 360. Then, the third insulation layer 160 may be formed by heating the residue 159, and the third insulation layer 160 may cover a space corresponding to the second sacrificial insulation layers 365. However, since the thickness of the first sacrificial insulation layer 325 may be greater than the thickness of the second sacrificial insulation layer 365, in some cases, the residue may not remain in the space corresponding to the first sacrificial insulation layers 325, even if the first sacrificial insulation layers 325 are etched by using the etchant described herein.

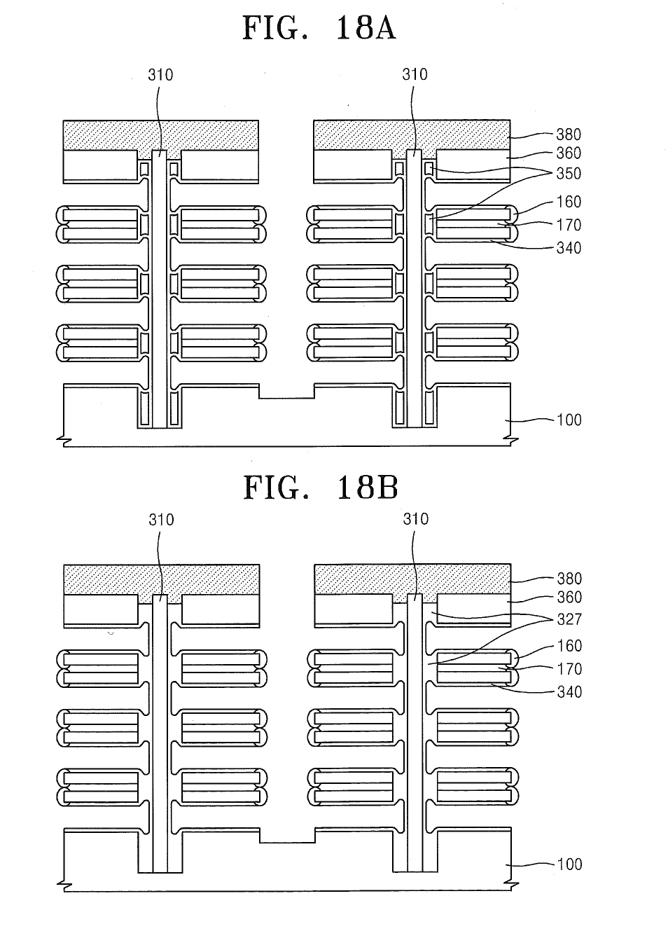

Referring to FIGS. 18A and 18B, the gate insulation layers 340 may be formed on the first insulation layers 360 and the channel layers 310 that are exposed by etching the first through third sacrificial insulation layers 325, 365, and 327. As described above, the gate insulation layers 340 may include the tunneling insulation layers 342, the charge storage layers 344, and the blocking insulation layers 346. As shown in FIG. 18A, if the gate insulation layers 340 with a poor step coverage are deposited, the second air gaps 350 may be formed between the plurality of the gate conductive layers 330 or between the topmost gate conductive layer 330 and the second insulation layers 370. Conversely, if the gate insulation layers 340 with a good step coverage are deposited as shown in FIG. 18B, the second air gaps 350 may not be formed. In this case, only the gate insulation layers 340 may be interposed between the gate conductive layers 330. As the gate insulation layers 340 are deposited, the first air gaps 170 may be formed between the residue 159 and the gate insulation layers 340.

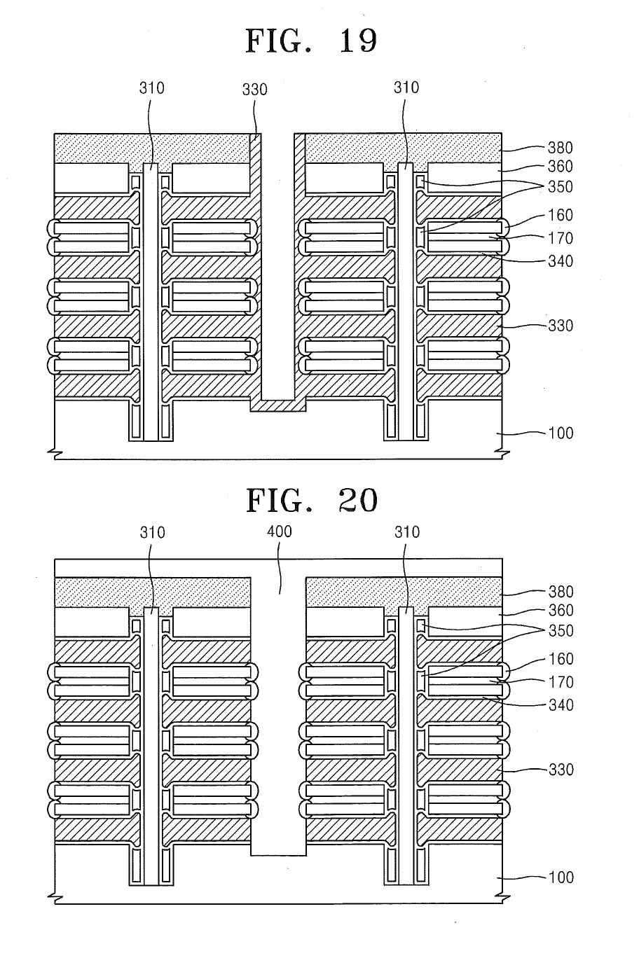

Referring to FIG. 19, the gate conductive layers 330 may be formed on the gate insulation layers 340. The gate conductive layers 330 formed between the first insulation layers 360 may function as wordlines. Next, referring to FIG. 20, a stripping operation may be performed to eliminate electrical connections between the gate conductive layers 330, and the separating insulation layers 400 for filling the wordline holes 405 may be formed.

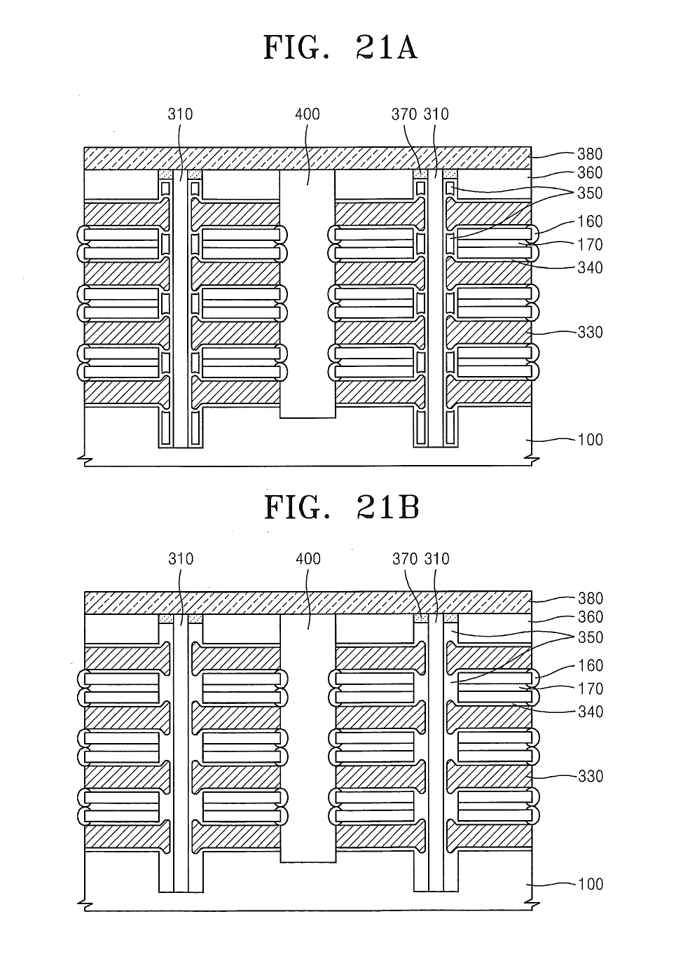

Referring to FIGS. 21A and 21B, the upper portions of the separating insulation layers 400 may be partially removed and the channel layers 310 may be exposed by performing a chemical mechanical polishing (CMP) operation. Next, the bitline conductive layer 380 may be formed on the first insulation layers 360, the second insulation layers 370, the channel layer 310, and the separating insulation layers 400. FIG. 21A shows the semiconductor device 300, in which the second air gaps 350 may be formed, whereas FIG. 21B shows the semiconductor device 300, in which the second air gaps 350 are not formed and only the gate insulation layers 340 are interposed between the gate conductive layers 330.

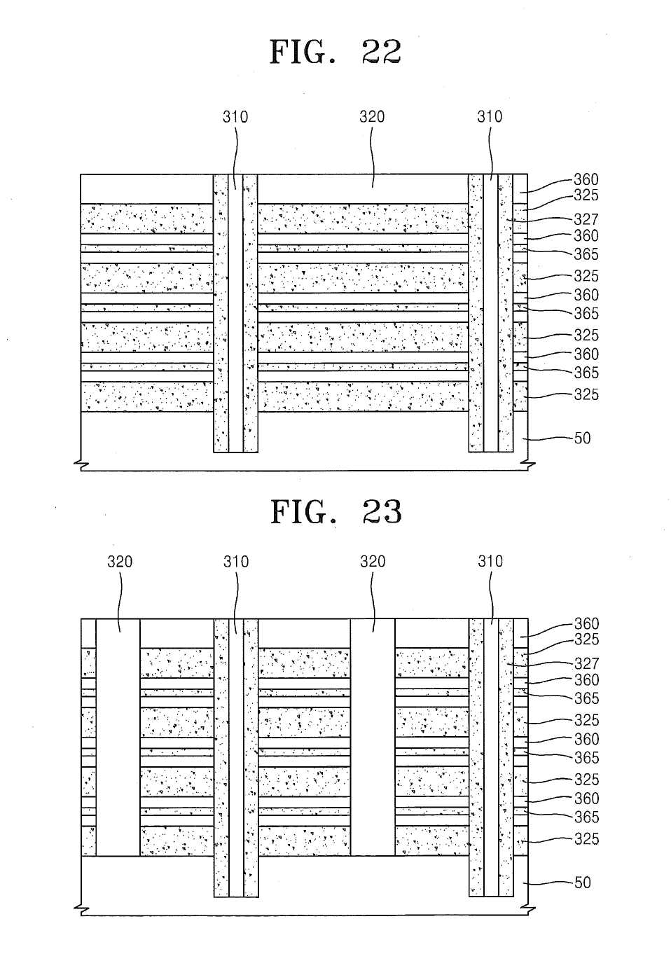

FIGS. 22 through 29 are sectional views sequentially showing each operation of a method of fabricating the semiconductor device 300 according to some embodiments of the invention. The methods may include the methods of fabricating the semiconductor device 300 shown with respect to FIG. 10. Furthermore, the methods may also include the methods of fabricating the semiconductor device 300 shown with respect to FIGS. 11 through 21B. As such, any redundant description will be omitted.

Referring to FIG. 22, the plurality of first sacrificial insulation layers 325, the plurality of second sacrificial insulation layers 365, and the plurality of first insulation layers 360 may be alternately stacked on the substrate 100, the plurality of channel holes 305 may be formed, and the third sacrificial insulation layers 327 and the channel layers 310 filling the channel holes 305 may be formed.

Referring to FIG. 23, dummy holes may be formed by etching the first and second sacrificial insulation layers 325 and 365 and the first insulation layers 360, and then the supporting insulation layers 320 for filling the dummy holes may be formed. The supporting insulation layers 320 may be formed of a material having an etching selectivity different from the first through third sacrificial insulation layers 325, 365, and 327.

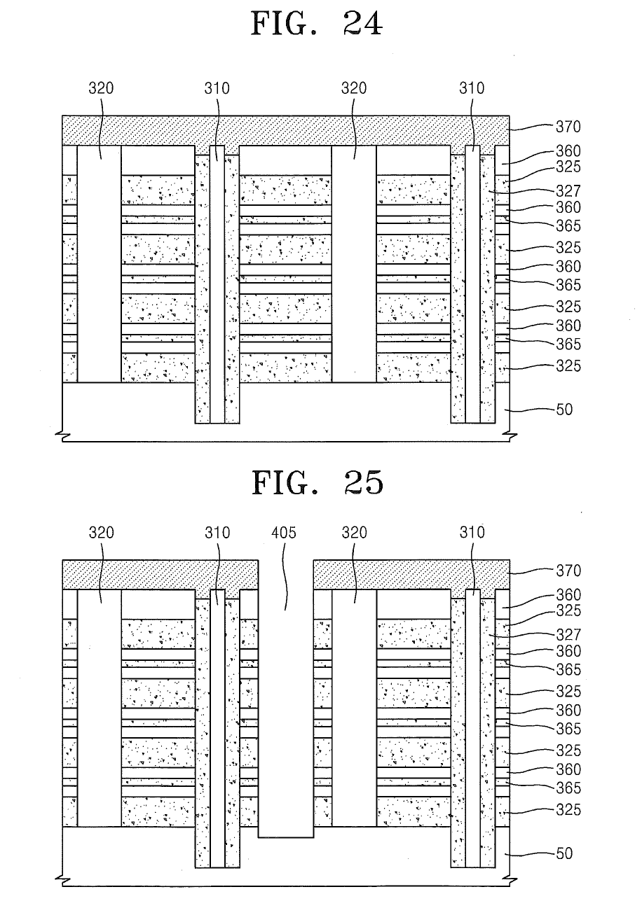

Referring to FIG. 24, as described above with reference to FIGS. 14 and 15, sidewalls of the topmost first insulation layer 360 and sidewalls of the channel layers 310 may be exposed by partially etching the upper portions of the third sacrificial insulation layers 327, and the second insulation layers 370 contacting the sidewalls of the topmost first insulation layer 360 and the sidewalls of the channel layers 310 may be formed.

Referring to FIG. 25, as described above with reference to FIG. 16, to perform the pull back process, in which the first through third sacrificial insulation layers 325, 365, and 327 are etched, the plurality of wordline holes 405 may be formed by etching the second insulation layers 370, the first sacrificial insulation layers 325, and the first insulation layers 360. In this case, each of the wordline holes 405 may be arranged between channel layers 310 and the supporting insulation layers 320.

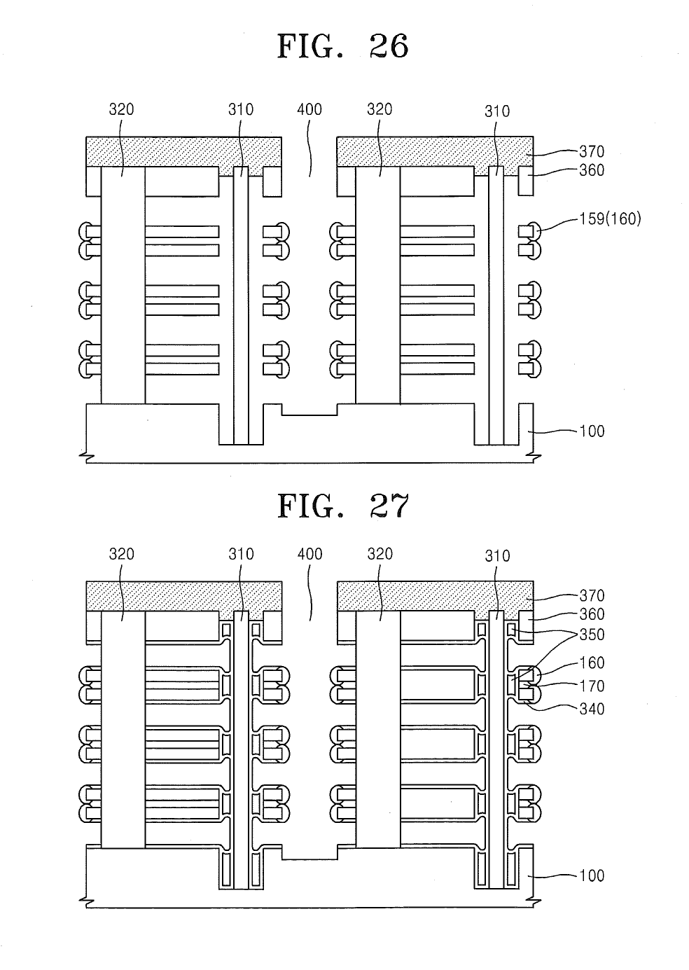

Referring to FIG. 26, as described above with reference to FIG. 17, the pull back process may be performed and the first sacrificial insulation layers 325, the second sacrificial insulation layers 365, and the third sacrificial insulation layers 327 may be etched. The supporting insulation layers 320 may prevent the first insulation layers 360 from collapsing after the first and second sacrificial insulation layers 325 and 365 are etched. Furthermore, as described above, as the second sacrificial insulation layers 365 may be etched, residue 159 of the second sacrificial insulation layers 365 may be formed on ends of the first insulation layers 360, and the third insulation layer 160 may be formed by heating the residue 159.

Referring to FIG. 27, as described above with reference to FIG. 18A, the gate insulation layers 340 may be formed on the exposed first insulation layers 360 and the exposed channel layers 310. As described above, if the gate insulation layers 340 having poor step coverage are deposited, the second air gaps 350 may be formed between the plurality of the gate conductive layers 330 or between the topmost gate conductive layer 330 and the second insulation layers 370. Conversely, although not shown, if the gate insulation layers 340 having good step coverage are deposited, the second air gaps 350 may not be formed as shown in FIG. 18B.

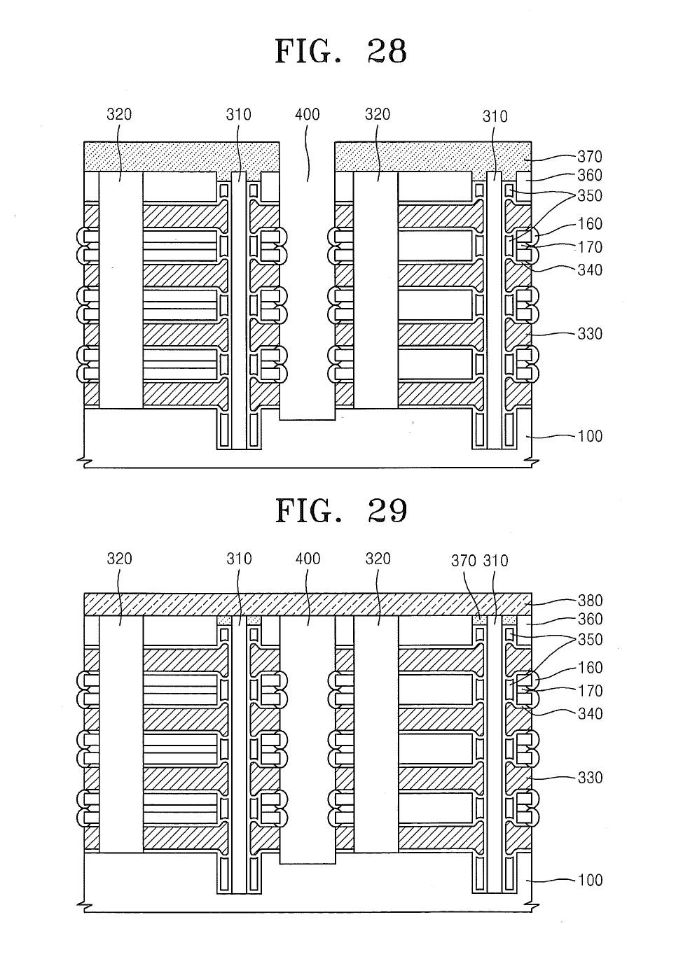

Referring to FIGS. 28 and 29, as described above with reference to FIGS. 19 through 21A, the gate conductive layers 330 may be formed on the gate insulation layers 340, and the separating insulation layers 400 for filling the wordline holes 405 may be formed. Furthermore, the upper portions of the separating insulation layers 400 and the second insulation layers 370 may be partially removed to expose the channel layers 310, and the bitline conductive layer 380 may be formed on the first insulation layers 360, the second insulation layers 370, the channel layer 310, the supporting insulation layers 320, and the separating insulation layers 400. Although not shown, if the gate insulation layers 340 with a good step coverage are deposited, the second air gaps 350 may not be formed as shown in FIG. 21B.

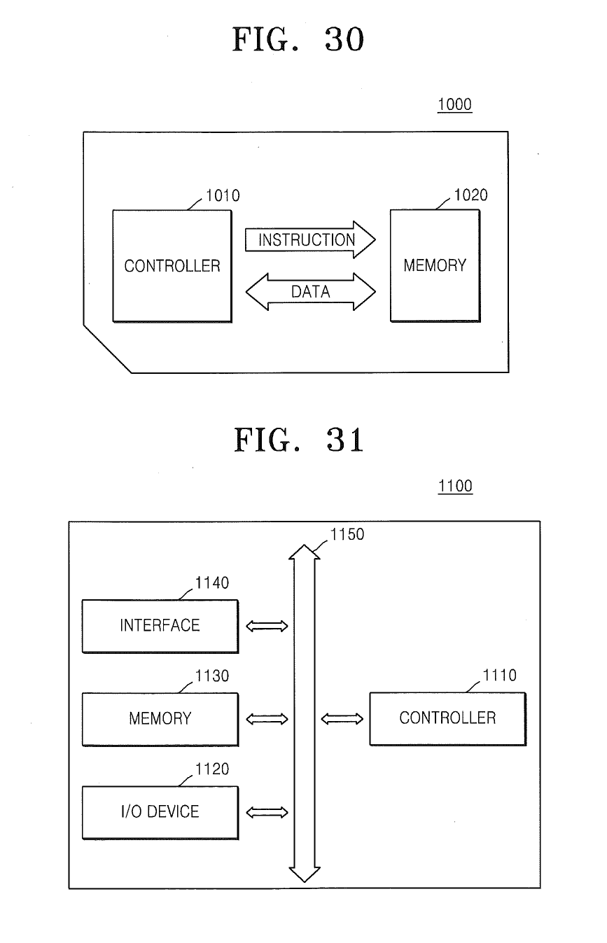

FIG. 30 is a diagram showing a card 1000 including a semiconductor device that is fabricated using a method of fabricating a semiconductor device according to some embodiments of the invention.

Referring to FIG. 30, a controller 1010 and a memory 1020 may be arranged to exchange electric signals. For example, when the controller 1010 provides an instruction, the memory 1020 may transmit data. The memory 1020 may include a semiconductor device that is fabricated using a method of fabricating a semiconductor device according to one of embodiments of the inventive concept. As known in the art, the semiconductor devices may be arranged as a “NAND” or “NOR” architecture memory array (not shown) in correspondence to the design of a corresponding logic. Memory arrays arranged in a plurality of columns and a plurality of rows may form one or more memory array banks (not shown). The memory 1020 may include such a memory array or a memory array bank. Furthermore, the card 1000 may further include a general row decoder (not shown), a general column decoder (not shown), I/O buffers (not shown), and/or a control register (not shown) for driving the memory array bank. The card 1000 may be embodied in any of various types of card-type memory devices, e.g. a memory stick card, a smart media (SM) card, a secure digital (SD) card, a mini SD card, or a multimedia card (MMC).

FIG. 31 is a diagram showing a system 1100 including a semiconductor device that is fabricated using a method of fabricating a semiconductor device according to some embodiments of the invention.

Referring to FIG. 31, the system 1100 may include a controller 1110, an I/O device 1120, a memory 1130, and an interface 1140. The system 1100 may be a mobile system or a system for transmitting or receiving data. Non-limiting examples of the mobile system include a personal digital assistant (PDA), a portable computer, a web tablet, a wireless phone, a mobile phone, a digital music player, and a memory card. The controller 1110 may launch programs and control the system 1100. The controller 1110 may be a microprocessor, a digital signal processor, a microcontroller, or the like, for example. The I/O device 1120 may be used to input data to or output data from the system 1100. The system 1100 may be connected to an external device, e.g. a personal computer or a network, via the I/O device 1120 and may exchange data with the external device. The I/O device 1120 may be a keypad, a keyboard, or a display device, for example. The memory 1130 may store codes and/or data for operating the controller 1110 and/or may store data processed by the controller 1110. The memory 1130 may include a semiconductor device that is fabricated using a method of fabricating a semiconductor device according to an embodiment of the inventive concept. The interface 1140 may be a data transmission path between the system 1100 and an external device. The controller 1110, the I/O device 1120, the memory 1130, and the interface 1140 may communicate with each other via a bus 1150. For example, the system 1100 may be used in a mobile phone, an MP3 player, a navigation device, a portable multimedia player (PMP), a solid state disk (SSD), or a household appliance.

The inventive concept will now be described more fully with reference to the accompanying drawings, in which exemplary embodiments of the inventive concept are shown. The inventive concept may, however, be embodied in many different forms and should not be construed as being limited to the embodiments set forth herein; rather, these embodiments are provided so that this disclosure will be thorough and complete, and will fully convey the inventive concept to those skilled in the art. In the drawings, the thicknesses of layers and regions are exaggerated for clarity. Like reference numerals in the drawings denote like elements, and thus their description will be omitted.

1. A method of fabricating a semiconductor device, the method comprising:
forming a plurality of gate patterns on a substrate;
forming first insulation layers between the gate patterns;
wet-etching the first insulation layers to form first insulation residues; and
forming air gaps between the plurality of gate patterns.

2. The method of claim 1, wherein the wet-etching is performed using an etchant comprising phosphoric acid (H₃PO₄) and silicon phosphate (Si₃(PO₄)₄).

3. The method of claim 2, wherein the concentration of Si in the etchant is from about 10 to about 1000 ppm with respect to the total weight of the etchant solution.

4. The method of claim 1, wherein the air gaps are formed between the substrate and the first insulation residues.

5. The method of claim 1, further comprising forming a second insulation layer on the substrate and on the gate patterns before forming the first insulation layers,
wherein the first insulation layers are selectively etched over the second insulation layer.

6. The method of claim 1, further comprising heating the first insulation residues to form third insulation layers.

7. The method of claim 6, wherein the third insulation layers have an etching selectivity different from that of the first insulation layers.

8. The method of claim 6, wherein the third insulation layers are on the gate patterns.

9. The method of claim 8, wherein the third insulation layers on the gate patterns contact each other.

10. The method of claim 8, wherein the third insulation layers on the gate patterns do not contact each other, so that there are slits between adjacent third insulation layers.

11. The method of claim 10, further comprising forming a fourth insulation layer on the third insulation layers that covers the slits between adjacent third insulation layers.

12. A method of fabricating a semiconductor device, the method comprising:
forming a plurality of gate patterns on a substrate;
forming a first oxide layer on the substrate and on the gate patterns;
forming nitride layers between the gate patterns;
forming a residue of the nitride layers by etching the nitride layers using an etchant comprising phosphoric acid (H₃PO₄) and silicon phosphate (Si₃(PO₄)₄); and
forming second oxide layers by heating the residue,
wherein air gaps are formed between the plurality of gate patterns.

13. The method of claim 12, wherein the concentration of Si in the etchant is from about 10 to about 1000 ppm with respect to the total weight of the etchant solution.

14. The method of claim 12, wherein the nitride layers are wet-etched at a temperature in a range of from about 25° C. to about 200° C. for a time period in a range from about 5 minutes to about 30 minutes.

15. The method of claim 12, wherein the second oxide layers are formed on the gate patterns.

16. The method of claim 15, wherein the second oxide layers formed on the gate patterns contact each other.

17. The method of claim 15, wherein the second oxide layers formed on the gate patterns do not contact each other, so that there are slits between adjacent second oxide layers.

18. The method of claim 17, further comprising forming a third oxide layer on the second oxide layers that covers the slits between adjacent second oxide layers.

19. An etchant comprising phosphoric acid (H₃PO₄) and silicon phosphate (Si₃(PO₄)₄).

20. The etchant of claim 19, wherein the concentration of Si in the etchant is from about 10 to about 1000 ppm with respect to the total weight of the etchant solution.

21-23. (canceled)

24. A semiconductor device comprising
a plurality of gate patterns; and
a silicon dioxide layer on the plurality of gate patterns; and
air gaps enclosed by the gate patterns and the silicon dioxide layer thereon.
